(19) United States
(12) Patent Application Publication
(10) Pub. No.: US 2022/0136098 A1
(43) Pub. Date: May 5, 2022

(54) Method for improving service life of magnetron

(71) Applicant: Sichuan University, Chengdu (CN)

(72) Inventors: Kama Huang, Chengdu (CN); Yang Yang, Chengdu (CN); Changjun Liu, Chengdu (CN); Huacheng Zhu, Chengdu (CN)

(21) Appl. No.: 17/576,794

(22) Filed: Jan. 14, 2022

(51) Int. Cl. C23C 14/35; H01J 37/34; H01J 37/32

(52) U.S. Cl. CPC C23C 14/357; H01J 37/32266; H01J 37/3405

(57) ABSTRACT

A method for improving service life of a magnetron, which belongs to the technical field of microwave applications, includes: taking anode working voltage range is taken as n voltage values U1 . . . Un constituting an arithmetic sequence; taking the voltage value as the anode voltage; in each voltage value, adjusting the magnet coil current between I min and Imax by the coil current control part , so that the output power P of the experimental magnetron is equal to the target power P0, and measuring the cathode filament temperature at this time by the temperature measuring part, which is denoted as Ti; measuring all the cathode filament temperatures Ti as the temperature data set corresponding to P0 by the temperature measuring part; taking out the minimum temperature value Tmin in the temperature data set, and using the anode voltage value and the magnet coil current value corresponding to Tmin as the working magnetron, wherein the output power is the anode voltage value and the magnet coil current value of P0. The present invention provides a method for improving the service life of a magnetron, which adjusts the electric field and the magnetic field, finds the synergy between the magnetic field and the electric field, and improves the service life of the magnetron.

### BACKGROUND OF THE PRESENT INVENTION

### Field of Invention

The present invention relates to the technical field of microwave application, and more particular to a method for improving the service life of a magnetron.

### Description of Related Arts

In chemical applications, it is often necessary to adjust the microwave power in real time according to the characteristics and process of the reactants. It is expected that the temperature of the reaction process will change according to the best temperature rise curve to ensure the high efficiency and safety of microwave heating chemical reactions. However, it has been found that the service life of the microwave source that adjusts the output power in engineering is very short, and the magnetron is often burned, which has become a world problem that limits the application of high-power microwaves in chemical industry.

The microwave output power of the magnetron is the product of the magnetron efficiency, the anode voltage and the anode current, and the anode current is not only related to the anode voltage, but also to the working magnetic field and the cathode filament current. So the independent factors that affect the microwave output power of the magnetron are anode voltage, working magnetic field and cathode filament current. When the working magnetic field and the cathode filament current are constant, the anode current rises sharply with the increase of the anode voltage, and the microwave output power of the magnetron rises correspondingly; when the anode voltage and the cathode filament current are constant, the anode current rises sharply with the working magnetic field when the anode voltage and the working magnetic field are constant, the anode current increases with the increase of the cathode filament current, and the microwave output power of the magnetron also increases; The variable that affects the working magnetic field is the magnet coil current. The larger the magnet coil current, the stronger the working magnetic field. In order to change the microwave output power of the magnetron, the main method at present is to change the anode voltage or change the magnet coil current. In the past, when the power of industrial high-power microwave sources was adjusted, the anode current and the magnet coil current were not jointly controlled according to the optimal ratio, the electrons did not move synchronously with the microwave field, and the magnetron could not work at the optimal working point, resulting in the magnetron The electrons in the tube are seriously bombarded, and the cathode filament is burned, which seriously shortens the service life of the magnetron.

### SUMMARY OF THE PRESENT INVENTION

An object of the present invention is to provide a method for improving a service life of the magnetron in view of the above shortcomings, and to solve the problems of how to improve the life of the magnetron. To achieve the above object, the present invention provides the following technical solutions.

A method for improving service life of a magnetron, comprises: adopting a control device, an experimental magnetron and a working magnetron; wherein the experimental magnetron comprises a cathode filament 1, a an anode 2 matching with the cathode filament 1, an electromagnet 3, a cathode power supply 4, an anode negative high-voltage power supply 5 and a magnetic field power supply 6; wherein the cathode power supply 4 is used for heating the cathode filament 1; the anode negative high-voltage power supply 5 is used for providing the anode voltage, so that the anode 2 and the cathode filament 1 are arranged to generate an electric field; the magnetic field power supply 6 is used for providing the coil of the electromagnet 3 with a magnet coil current, in such a manner that the electromagnet 3 generates a magnetic field of an orthogonal electric field; the control device comprises an anode current measuring part 7 for measuring anode current, an anode negative high voltage measuring part 8 for measuring anode voltage; a coil current measuring unit 9 for measuring magnet coil current, an anode negative high voltage control unit 10 for changing anode voltage, a coil current control unit 11 for changing magnet coil current, and a temperature measuring unit 12 for measuring a temperature of the cathode filament 1; wherein the method specifically comprise steps of:

step (1): setting experimental magnetron target output power to be P0, working voltage range of the anode 2 in a range of Umin-Umax, and magnet coil working current to be in a range of Imin-Imax;

step (2): taking n voltage values U1, U2 . . . Un forming an arithmetic progression from the working voltage range Umin˜Umax of the anode 2, wherein U1=Umin, Un=Umax;

step (3): taking a first voltage value in the arithmetic sequence as the anode voltage Ui;

step (4): by the anode negative high voltage control part 10, controlling the anode negative high voltage power supply 5 to provide the anode voltage for Ui, and reading the anode voltage value by the anode negative high voltage measuring part 8;

step (5): when the anode negative high voltage measuring unit 8 reads the anode voltage as Ui, controlling the magnetic field power supply 6 by the coil current control unit 11 to adjust the magnet coil current between Imin and Imax; reading the magnet coil current value Ic in real time by the coil current measuring unit 9; reading the anode current value Ia in real time by the anode current measuring section 7; according to the anode current value Ia and the anode voltage value Ui, when the experimental magnetron output power P is calculated to be equal to P0, performing step 6; if the output power P of the experimental magnetron is not equal to P0, then performing step 7;

step (6): by the temperature measuring part 12, measuring the temperature of the cathode filament 1 as Ti; and recording the anode voltage value Ui and the magnet coil current value Ic when the experimental magnetron output power P is equal to P0;

step (7): if Ui is not a last value of the arithmetic sequence, performing step (8); otherwise performing step 9;

step (8): taking a voltage value of a next digit of Ui in the arithmetic sequence as Ui, and performing step (4);

step (9): adopting the temperature measuring unit 12 to measure the temperature Ti of all the cathode filaments 1, and taking Ti as the temperature data set corresponding to P0; taking out a minimum temperature value Tmin in the temperature data set, an anode voltage value and a current value of the magnet coil corresponding to Tmin;

step (10): taking the anode voltage value and the current value of the magnet coil corresponding to Tmin obtained in step (9) as the anode voltage value and the magnet coil current value with the output power of the working magnetron being P0.

Preferably, the control device further comprises an anode working voltage minimum value input part, an anode working voltage maximum value input part, a voltage value quantity part and an arithmetic sequence calculation part; wherein the anode working voltage minimum value input part is used for inputting a anode working voltage minimum value Umin; the anode working voltage maximum value input part is used for inputting a anode working voltage maximum value Umax; the voltage value quantity part is used for inputting an amount of a voltage values n of the arithmetic sequence; and the arithmetic sequence calculation part is used for receiving the values Umin, Umax and n, and calculating voltage values U1, U2 . . . Un constituting the arithmetic sequence; wherein the arithmetic sequence calculation unit sequentially inputs the voltage values in the arithmetic sequence to the anode negative high voltage control unit (10).

Preferably, the control device further comprises a target power input part and a power calculation part; the target power input part is used for inputting the experimental magnetron target output power P0 to the power calculation part; the power calculation part is used for calculating the experimental magnetron output power P according to the anode current the anode current value Ia read in real time by the anode current measuring part 7 and the anode voltage value Ui read by the anode negative high voltage measuring unit 8, and determining whether P is equal to P0.

Preferably, the control device further comprises a magnet coil working current minimum value input part and a magnet coil working current maximum value input part; the magnet coil working current minimum value input part is used for inputting the magnet coil working current minimum value Imin; the magnet coil working current maximum value input part is used for inputting the maximum value Imax of the working current of the magnet coil; the coil current control part 11 receives Imin and Imax, and controls the magnetic field power supply 6 to adjust the magnet coil current among Imin-Imax.

Preferably, the control device further comprises a temperature data set storage part; when the power calculation part judges that P is equal to P0, the temperature data set storage part stores a temperature Ti of the cathode filament 1 measured by the temperature measurement part 12, and stores a corresponding temperature of each Ti and the anode voltage value Ui and the magnet coil current value Ic; and the temperature data set storage unit stores all temperatures Ti of the cathode filament 1 to form a temperature data set.

Preferably, the control device further comprises a parameter screening part; wherein the parameter screening part is configured to screen out the minimum temperature value Tmin in the temperature data set, read the anode voltage value and the magnet coil current value corresponding to Tmin, and output the anode voltage value and the current value of the magnet coil to the working magnetron.

The beneficial effects of the present invention are:

The present invention discloses a method for improving the service life of a magnetron, which belongs to the technical field of microwave applications. The anode working voltage range is taken as n voltage values U1 . . . Un constituting an arithmetic sequence; The voltage value is taken as the anode voltage; in each voltage value, the coil current control part adjusts the magnet coil current between Imin and Imax, so that the output power P of the experimental magnetron is equal to the target power P0, and the temperature measuring part measures the cathode filament temperature at this time. It is Ti; the temperature measuring part measures all the cathode filament temperatures Ti as the temperature data set corresponding to P0; take out the minimum temperature value Tmin in the temperature data set, and use the anode voltage value and the magnet coil current value corresponding to Tmin as the working magnetron The output power is the anode voltage value and the magnet coil current value of P0. The invention provides a method for improving the service life of a magnetron, which adjusts the electric field and the magnetic field, finds the synergy between the magnetic field and the electric field, and improves the service life of the magnetron.

### BRIEF DESCRIPTION OF THE DRAWINGS

FIG. 1 is the structure schematic diagram of the control equipment according to a preferred embodiment of the present invention and the experimental magnetron;

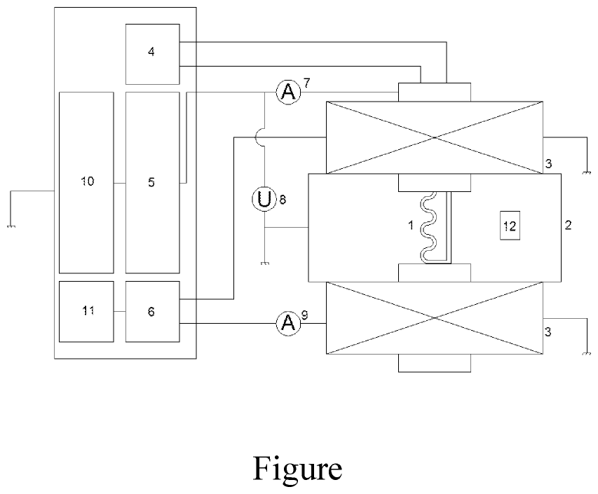

In the accompanying drawings: 1-cathode filament, 2-anode, 3-electromagnet, 4-cathode power supply, 5-anode negative high voltage power supply, 6-magnetic field power supply, 7-anode current measurement part, 8-anode negative high voltage measurement part, 9-coil current measurement part, 10-anode negative high voltage control part, 11-coil current control part, 12-temperature measurement part.

### DETAILED DESCRIPTION OF THE PREFERRED EMBODIMENT

The present invention will be described in further detail below with reference to the accompanying drawings and specific embodiments, but the present invention is not limited to the following embodiments.

### Embodiment 1

A method for improving service life of a magnetron, comprises: adopting a control device, an experimental magnetron and a working magnetron; wherein the experimental magnetron comprises a cathode filament 1, a an anode 2 matching with the cathode filament 1, an electromagnet 3, a cathode power supply 4, an anode negative high-voltage power supply 5 and a magnetic field power supply 6; wherein the cathode power supply 4 is used for heating the cathode filament 1; the anode negative high-voltage power supply 5 is used for providing the anode voltage, so that the anode 2 and the cathode filament 1 are arranged to generate an electric field; the magnetic field power supply 6 is used for providing the coil of the electromagnet 3 with a magnet coil current, in such a manner that the electromagnet 3 generates a magnetic field of an orthogonal electric field; the control device comprises an anode current measuring part 7 for measuring anode current, an anode negative high voltage measuring part 8 for measuring anode voltage; a coil current measuring unit 9 for measuring magnet coil current, an anode negative high voltage control unit 10 for changing anode voltage, a coil current control unit 11 for changing magnet coil current, and a temperature measuring unit 12 for measuring a temperature of the cathode filament 1; wherein the method specifically comprise steps of:

step (1): setting experimental magnetron target output power to be P0, working voltage range of the anode 2 in a range of Umin-Umax, and magnet coil working current to be in a range of Imin-Imax;

step (2): taking n voltage values U1, U2 . . . Un forming an arithmetic progression from the working voltage range Umin˜Umax of the anode 2, wherein U1=Umin, Un=Umax;

step (3): taking a first voltage value in the arithmetic sequence as the anode voltage Ui;

step (4): by the anode negative high voltage control part 10, controlling the anode negative high voltage power supply 5 to provide the anode voltage for Ui, and reading the anode voltage value by the anode negative high voltage measuring part 8;

step (5): when the anode negative high voltage measuring unit 8 reads the anode voltage as Ui, controlling the magnetic field power supply 6 by the coil current control unit 11 to adjust the magnet coil current between Imin and Imax; reading the magnet coil current value Ic in real time by the coil current measuring unit 9; reading the anode current value Ia in real time by the anode current measuring section 7; according to the anode current value Ia and the anode voltage value Ui, when the experimental magnetron output power P is calculated to be equal to P0, performing step 6; if the output power P of the experimental magnetron is not equal to P0, then performing step 7;

step (6): by the temperature measuring part 12, measuring the temperature of the cathode filament 1 as Ti; and recording the anode voltage value Ui and the magnet coil current value Ic when the experimental magnetron output power P is equal to P0;

step (7): if Ui is not a last value of the arithmetic sequence, performing step (8);

otherwise performing step 9;

step (8): taking a voltage value of a next digit of Ui in the arithmetic sequence as Ui, and performing step (4);

step (9): adopting the temperature measuring unit 12 to measure the temperature Ti of all the cathode filaments 1, and taking Ti as the temperature data set corresponding to P0; taking out a minimum temperature value Tmin in the temperature data set, an anode voltage value and a current value of the magnet coil corresponding to Tmin;

step (10): taking the anode voltage value and the current value of the magnet coil corresponding to Tmin obtained in step (9) as the anode voltage value and the magnet coil current value with the output power of the working magnetron being P0.

The experimental magnetron and the working magnetron are magnetrons of the same specification. The optimal cooperative array of the anode voltage value and the magnet coil current value when the target output power P0 is measured by the control equipment and the experimental magnetron can be obtained. The optimal cooperative array of the anode voltage value and the magnet coil current value of the magnetron under the target output power P0, all working magnetrons of the same specification can be set according to this parameter. Under the target output power P0, there are multiple arrays of anode voltage values and magnet coil current values. The best way to determine the best collaborative array is to measure the temperature of the cathode filament 1. The lower the temperature Ti of the cathode filament 1, the longer the life of the magnetron. The longer it is, the less likely it will be damaged. Take n voltage values U1, U2 . . . Un from the operating voltage range Umin˜Umax of anode 2 that form an arithmetic sequence. The more the number of n is, the closer the minimum temperature value Tmin in the obtained temperature data set is to the target output. The optimal operating point under the power P0, the anode voltage value and the magnet coil current value corresponding to the obtained Tmin are closer to the optimal cooperative array. Both the experimental magnetron and the working magnetron will give the working voltage range Umin˜Umax of anode 2 and the working current range Imin˜Imax of the magnet coil. to find the optimal cooperative array of anode voltage value and magnet coil current value under the target output power P0. The cathode power source 4 is used to heat the cathode filament 1, the cathode filament 1 emits thermionic electrons, and the anode negative high-voltage power supply 5 generates a sufficiently strong electric field between the cathode filament 1 and the anode 2 surrounding the cathode filament 1, so that thermionic electrons are directed to the anode 2. The magnetic field power source 6 is used to provide the coil of the electromagnet 3 with a magnet coil current, so that the electromagnet 3 generates a magnetic field of an orthogonal electric field, and the hot electrons enter the orthogonal electromagnetic field to rotate at a high speed to realize the conversion of kinetic energy to microwave energy. First, the first voltage value U1 in the arithmetic sequence is taken as the anode voltage Ui, the anode negative high voltage control part 10 controls the anode negative high voltage power supply 5 to provide the anode voltage of Ui, and the anode negative high voltage measuring part 8 reads the anode voltage value. The taken voltage value is greater than Ui, then the anode negative high voltage control part 10 controls the anode voltage provided by the anode negative high voltage power supply 5 to drop, if the read voltage value is less than Ui, then the anode negative high voltage control part 10 controls the anode negative high voltage power supply 5 to provide. The anode voltage rises until the anode negative high voltage power supply 5 provides the anode voltage of Ui; then for the anode voltage of Ui, the coil current control part 11 controls the magnetic field power supply 6 to adjust the magnet coil current between Imin˜Imax, and the coil current measuring part 9 real-time Read the magnet coil current value Ic, ensure that the magnet coil current value Ic gradually changes between Imin˜Imax, and the anode current is also constantly changing at this time. The anode current measuring unit 7 reads the anode current value in real time as Ia. When the output power P of the experimental magnetron is calculated from the value Ia and the anode voltage value Ui, when the output power P of the experimental magnetron is equal to P0, the temperature measuring part 12 measures the temperature of the cathode filament 1 as Ti; and records the anode voltage value Ui and The magnet coil current value Ic; then continue to use the next voltage value in the arithmetic sequence as the anode voltage Ui, continue to obtain the experimental magnetron output power P when the output power P is equal to P0, the temperature measuring section 12 measures the cathode filament 1 The temperature is Ti; until etc. The voltage values in the difference series are used as the anode voltage Ui, and the temperature measurement unit 12 measures all the cathode filament 1 temperatures Ti as the temperature data set corresponding to P0; take out the minimum temperature value Tmin in the temperature data set, and the anode voltage value corresponding to Tmin and the current value of the magnet coil; the anode voltage value and the magnet coil current value corresponding to Tmin are used as the anode voltage value and the magnet coil current value when the output power of the working magnetron is P0, that is, when the output power of the working magnetron is P0, Tmin corresponds to The anode voltage value and the magnet coil current value are the best cooperative array, the anode current and the magnet coil current are jointly controlled according to the best ratio, the electrons and the microwave field move synchronously, the magnetron works at the best working point, reducing the magnetron, the electrons in the tube bounce back, extending the service life of the magnetron. The anode current measuring unit 7, the anode negative high voltage measuring unit 8, and the coil current measuring unit 9 use conventional voltage and current detection modules; the temperature measuring unit 12 uses a radiation temperature measuring instrument.

### Embodiment 2

A method for improving service life of a magnetron, comprises: adopting a control device, an experimental magnetron and a working magnetron; wherein the experimental magnetron comprises a cathode filament 1, a an anode 2 matching with the cathode filament 1, an electromagnet 3, a cathode power supply 4, an anode negative high-voltage power supply 5 and a magnetic field power supply 6; wherein the cathode power supply 4 is used for heating the cathode filament 1; the anode negative high-voltage power supply 5 is used for providing the anode voltage, so that the anode 2 and the cathode filament 1 are arranged to generate an electric field; the magnetic field power supply 6 is used for providing the coil of the electromagnet 3 with a magnet coil current, in such a manner that the electromagnet 3 generates a magnetic field of an orthogonal electric field; the control device comprises an anode current measuring part 7 for measuring anode current, an anode negative high voltage measuring part 8 for measuring anode voltage; a coil current measuring unit 9 for measuring magnet coil current, an anode negative high voltage control unit 10 for changing anode voltage, a coil current control unit 11 for changing magnet coil current, and a temperature measuring unit 12 for measuring a temperature of the cathode filament 1; wherein the method specifically comprise steps of:

step (1): setting experimental magnetron target output power to be P0, working voltage range of the anode 2 in a range of Umin-Umax, and magnet coil working current to be in a range of Imin-Imax;

step (2): taking n voltage values U1, U2 . . . Un forming an arithmetic progression from the working voltage range Umin˜Umax of the anode 2, wherein U1=Umin, Un=Umax;

step (3): taking a first voltage value in the arithmetic sequence as the anode voltage Ui;

step (4): by the anode negative high voltage control part 10, controlling the anode negative high voltage power supply 5 to provide the anode voltage for Ui, and reading the anode voltage value by the anode negative high voltage measuring part 8;

step (5): when the anode negative high voltage measuring unit 8 reads the anode voltage as Ui, controlling the magnetic field power supply 6 by the coil current control unit 11 to adjust the magnet coil current between Imin and Imax; reading the magnet coil current value Ic in real time by the coil current measuring unit 9; reading the anode current value Ia in real time by the anode current measuring section 7; according to the anode current value Ia and the anode voltage value Ui, when the experimental magnetron output power P is calculated to be equal to P0, performing step 6; if the output power P of the experimental magnetron is not equal to P0, then performing step 7;

step (6): by the temperature measuring part 12, measuring the temperature of the cathode filament 1 as Ti; and recording the anode voltage value Ui and the magnet coil current value Ic when the experimental magnetron output power P is equal to P0;

step (7): if Ui is not a last value of the arithmetic sequence, performing step (8); otherwise performing step 9;

step (8): taking a voltage value of a next digit of Ui in the arithmetic sequence as Ui, and performing step (4);

step (9): adopting the temperature measuring unit 12 to measure the temperature Ti of all the cathode filaments 1, and taking Ti as the temperature data set corresponding to P0; taking out a minimum temperature value Tmin in the temperature data set, an anode voltage value and a current value of the magnet coil corresponding to Tmin;

step (10): taking the anode voltage value and the current value of the magnet coil corresponding to Tmin obtained in step (9) as the anode voltage value and the magnet coil current value with the output power of the working magnetron being P0.

The experimental magnetron and the working magnetron are magnetrons of the same specification. The optimal cooperative array of the anode voltage value and the magnet coil current value when the target output power P0 is measured by the control equipment and the experimental magnetron can be obtained. The optimal cooperative array of the anode voltage value and the magnet coil current value of the magnetron under the target output power P0, all working magnetrons of the same specification can be set according to this parameter. Under the target output power P0, there are multiple arrays of anode voltage values and magnet coil current values. The best way to determine the best collaborative array is to measure the temperature of the cathode filament 1. The lower the temperature Ti of the cathode filament 1, the longer the life of the magnetron. The longer it is, the less likely it will be damaged. Take n voltage values U1, U2 . . . Un from the operating voltage range Umin˜Umax of anode 2 that form an arithmetic sequence. The more the number of n is, the closer the minimum temperature value Tmin in the obtained temperature data set is to the target output. The optimal operating point under the power P0, the anode voltage value and the magnet coil current value corresponding to the obtained Tmin are closer to the optimal cooperative array. Both the experimental magnetron and the working magnetron will give the working voltage range Umin-Umax of anode 2 and the working current range Imin-Imax of the magnet coil. to find the optimal cooperative array of anode voltage value and magnet coil current value under the target output power P0. The cathode power source 4 is used to heat the cathode filament 1, the cathode filament 1 emits thermionic electrons, and the anode negative high-voltage power supply 5 generates a sufficiently strong electric field between the cathode filament 1 and the anode 2 surrounding the cathode filament 1, so that thermionic electrons are directed to the anode 2. The magnetic field power source 6 is used to provide the coil of the electromagnet 3 with a magnet coil current, so that the electromagnet 3 generates a magnetic field of an orthogonal electric field, and the hot electrons enter the orthogonal electromagnetic field to rotate at a high speed to realize the conversion of kinetic energy to microwave energy. First, the first voltage value U1 in the arithmetic sequence is taken as the anode voltage Ui, the anode negative high voltage control part 10 controls the anode negative high voltage power supply 5 to provide the anode voltage of Ui, and the anode negative high voltage measuring part 8 reads the anode voltage value. The taken voltage value is greater than Ui, then the anode negative high voltage control part 10 controls the anode voltage provided by the anode negative high voltage power supply 5 to drop, if the read voltage value is less than Ui, then the anode negative high voltage control part 10 controls the anode negative high voltage power supply 5 to provide. The anode voltage rises until the anode negative high voltage power supply 5 provides the anode voltage of Ui; then for the anode voltage of Ui, the coil current control part 11 controls the magnetic field power supply 6 to adjust the magnet coil current between Imin˜Imax, and the coil current measuring part 9 real-time Read the magnet coil current value Ic, ensure that the magnet coil current value Ic gradually changes between Imin˜Imax, and the anode current is also constantly changing at this time. The anode current measuring unit 7 reads the anode current value in real time as Ia. When the output power P of the experimental magnetron is calculated from the value Ia and the anode voltage value Ui, when the output power P of the experimental magnetron is equal to P0, the temperature measuring part 12 measures the temperature of the cathode filament 1 as Ti; and records the anode voltage value Ui and The magnet coil current value Ic; then continue to use the next voltage value in the arithmetic sequence as the anode voltage Ui, continue to obtain the experimental magnetron output power P when the output power P is equal to P0, the temperature measuring section 12 measures the cathode filament 1 The temperature is Ti; until etc. The voltage values in the difference series are used as the anode voltage Ui, and the temperature measurement unit 12 measures all the cathode filament 1 temperatures Ti as the temperature data set corresponding to P0; take out the minimum temperature value Tmin in the temperature data set, and the anode voltage value corresponding to Tmin and the current value of the magnet coil; the anode voltage value and the magnet coil current value corresponding to Tmin are used as the anode voltage value and the magnet coil current value when the output power of the working magnetron is P0, that is, when the output power of the working magnetron is P0, Tmin corresponds to The anode voltage value and the magnet coil current value are the best cooperative array, the anode current and the magnet coil current are jointly controlled according to the best ratio, the electrons and the microwave field move synchronously, the magnetron works at the best working point, reducing the magnetron, the electrons in the tube bounce back, extending the service life of the magnetron. The anode current measuring unit 7 , the anode negative high voltage measuring unit 8 , and the coil current measuring unit 9 use conventional voltage and current detection modules; the temperature measuring unit 12 uses a radiation temperature measuring instrument.

The control device further comprises an anode working voltage minimum value input part, an anode working voltage maximum value input part, a voltage value quantity part and an arithmetic sequence calculation part; wherein the anode working voltage minimum value input part is used for inputting a anode working voltage minimum value Umin; the anode working voltage maximum value input part is used for inputting a anode working voltage maximum value Umax; the voltage value quantity part is used for inputting an amount of a voltage values n of the arithmetic sequence; and the arithmetic sequence calculation part is used for receiving the values Umin, Umax and n, and calculating voltage values U1, U2 . . . Un constituting the arithmetic sequence; wherein the arithmetic sequence calculation unit sequentially inputs the voltage values in the arithmetic sequence to the anode negative high voltage control unit (10).

According to the specifications of the experimental magnetron itself, input the minimum value of the anode working voltage Umin in the input part of the minimum value of the anode operating voltage, input the maximum value of the anode operating voltage Umax in the input part of the maximum value of the anode operating voltage, and input the equal difference in the part of the voltage value quantity. The number of voltage values of the sequence is n, and the arithmetic sequence calculation part calculates the voltage values U1, U2 . . . The voltage value is input to the anode negative high voltage control unit 10, and the anode negative high voltage control unit 10 controls the anode negative high voltage power supply 5 to supply the voltage value of the arithmetic sequence as the anode voltage.

### Embodiment 3

A method for improving service life of a magnetron, comprises: adopting a control device, an experimental magnetron and a working magnetron; wherein the experimental magnetron comprises a cathode filament 1, a an anode 2 matching with the cathode filament 1, an electromagnet 3, a cathode power supply 4, an anode negative high-voltage power supply 5 and a magnetic field power supply 6; wherein the cathode power supply 4 is used for heating the cathode filament 1; the anode negative high-voltage power supply 5 is used for providing the anode voltage, so that the anode 2 and the cathode filament 1 are arranged to generate an electric field; the magnetic field power supply 6 is used for providing the coil of the electromagnet 3 with a magnet coil current, in such a manner that the electromagnet 3 generates a magnetic field of an orthogonal electric field; the control device comprises an anode current measuring part 7 for measuring anode current, an anode negative high voltage measuring part 8 for measuring anode voltage; a coil current measuring unit 9 for measuring magnet coil current, an anode negative high voltage control unit 10 for changing anode voltage, a coil current control unit 11 for changing magnet coil current, and a temperature measuring unit 12 for measuring a temperature of the cathode filament 1; wherein the method specifically comprise steps of:

step (1): setting experimental magnetron target output power to be P0, working voltage range of the anode 2 in a range of Umin-Umax, and magnet coil working current to be in a range of Imin-Imax;

step (2): taking n voltage values U1, U2 . . . Un forming an arithmetic progression from the working voltage range Umin˜Umax of the anode 2, wherein U1=Umin, Un=Umax;

step (3): taking a first voltage value in the arithmetic sequence as the anode voltage Ui;

step (4): by the anode negative high voltage control part 10, controlling the anode negative high voltage power supply 5 to provide the anode voltage for Ui, and reading the anode voltage value by the anode negative high voltage measuring part 8;

step (5): when the anode negative high voltage measuring unit 8 reads the anode voltage as Ui, controlling the magnetic field power supply 6 by the coil current control unit 11 to adjust the magnet coil current between Imin and Imax; reading the magnet coil current value Ic in real time by the coil current measuring unit 9; reading the anode current value Ia in real time by the anode current measuring section 7; according to the anode current value Ia and the anode voltage value Ui, when the experimental magnetron output power P is calculated to be equal to P0, performing step 6; if the output power P of the experimental magnetron is not equal to P0, then performing step 7;

step (6): by the temperature measuring part 12, measuring the temperature of the cathode filament 1 as Ti; and recording the anode voltage value Ui and the magnet coil current value Ic when the experimental magnetron output power P is equal to P0;

step (7): if Ui is not a last value of the arithmetic sequence, performing step (8);

otherwise performing step 9;

step (8): taking a voltage value of a next digit of Ui in the arithmetic sequence as Ui, and performing step (4);

step (9): adopting the temperature measuring unit 12 to measure the temperature Ti of all the cathode filaments 1, and taking Ti as the temperature data set corresponding to P0; taking out a minimum temperature value Tmin in the temperature data set, an anode voltage value and a current value of the magnet coil corresponding to Tmin;

step (10): taking the anode voltage value and the current value of the magnet coil corresponding to Tmin obtained in step (9) as the anode voltage value and the magnet coil current value with the output power of the working magnetron being P0.

The experimental magnetron and the working magnetron are magnetrons of the same specification. The optimal cooperative array of the anode voltage value and the magnet coil current value when the target output power P0 is measured by the control equipment and the experimental magnetron can be obtained. The optimal cooperative array of the anode voltage value and the magnet coil current value of the magnetron under the target output power P0, all working magnetrons of the same specification can be set according to this parameter. Under the target output power P0, there are multiple arrays of anode voltage values and magnet coil current values. The best way to determine the best collaborative array is to measure the temperature of the cathode filament 1. The lower the temperature Ti of the cathode filament 1, the longer the life of the magnetron. The longer it is, the less likely it will be damaged. Take n voltage values U1, U2 . . . Un from the operating voltage range Umin˜Umax of anode 2 that form an arithmetic sequence. The more the number of n is, the closer the minimum temperature value Tmin in the obtained temperature data set is to the target output. The optimal operating point under the power P0, the anode voltage value and the magnet coil current value corresponding to the obtained Tmin are closer to the optimal cooperative array. Both the experimental magnetron and the working magnetron will give the working voltage range Umin-Umax of anode 2 and the working current range Imin-Imax of the magnet coil. to find the optimal cooperative array of anode voltage value and magnet coil current value under the target output power P0. The cathode power source 4 is used to heat the cathode filament 1, the cathode filament 1 emits thermionic electrons, and the anode negative high-voltage power supply 5 generates a sufficiently strong electric field between the cathode filament 1 and the anode 2 surrounding the cathode filament 1, so that thermionic electrons are directed to the anode 2. The magnetic field power source 6 is used to provide the coil of the electromagnet 3 with a magnet coil current, so that the electromagnet 3 generates a magnetic field of an orthogonal electric field, and the hot electrons enter the orthogonal electromagnetic field to rotate at a high speed to realize the conversion of kinetic energy to microwave energy. First, the first voltage value U1 in the arithmetic sequence is taken as the anode voltage Ui, the anode negative high voltage control part 10 controls the anode negative high voltage power supply 5 to provide the anode voltage of Ui, and the anode negative high voltage measuring part 8 reads the anode voltage value. The taken voltage value is greater than Ui, then the anode negative high voltage control part 10 controls the anode voltage provided by the anode negative high voltage power supply 5 to drop, if the read voltage value is less than Ui, then the anode negative high voltage control part 10 controls the anode negative high voltage power supply 5 to provide. The anode voltage rises until the anode negative high voltage power supply 5 provides the anode voltage of Ui; then for the anode voltage of Ui, the coil current control part 11 controls the magnetic field power supply 6 to adjust the magnet coil current between Imin-Imax, and the coil current measuring part 9 real-time Read the magnet coil current value Ic, ensure that the magnet coil current value Ic gradually changes between Imin-Imax, and the anode current is also constantly changing at this time. The anode current measuring unit 7 reads the anode current value in real time as Ia. When the output power P of the experimental magnetron is calculated from the value Ia and the anode voltage value Ui, when the output power P of the experimental magnetron is equal to P0, the temperature measuring part 12 measures the temperature of the cathode filament 1 as Ti; and records the anode voltage value Ui and The magnet coil current value Ic; then continue to use the next voltage value in the arithmetic sequence as the anode voltage Ui, continue to obtain the experimental magnetron output power P when the output power P is equal to P0, the temperature measuring section 12 measures the cathode filament 1 The temperature is Ti; until etc. The voltage values in the difference series are used as the anode voltage Ui, and the temperature measurement unit 12 measures all the cathode filament 1 temperatures Ti as the temperature data set corresponding to P0; take out the minimum temperature value Tmin in the temperature data set, and the anode voltage value corresponding to Tmin and the current value of the magnet coil; the anode voltage value and the magnet coil current value corresponding to Tmin are used as the anode voltage value and the magnet coil current value when the output power of the working magnetron is P0, that is, when the output power of the working magnetron is P0, Tmin corresponds to The anode voltage value and the magnet coil current value are the best cooperative array, the anode current and the magnet coil current are jointly controlled according to the best ratio, the electrons and the microwave field move synchronously, the magnetron works at the best working point, reducing the magnetron, the electrons in the tube bounce back, extending the service life of the magnetron. The anode current measuring unit 7 , the anode negative high voltage measuring unit 8 , and the coil current measuring unit 9 use conventional voltage and current detection modules; the temperature measuring unit 12 uses a radiation temperature measuring instrument.

The control device further comprises an anode working voltage minimum value input part, an anode working voltage maximum value input part, a voltage value quantity part and an arithmetic sequence calculation part; wherein the anode working voltage minimum value input part is used for inputting a anode working voltage minimum value Umin; the anode working voltage maximum value input part is used for inputting a anode working voltage maximum value Umax; the voltage value quantity part is used for inputting an amount of a voltage values n of the arithmetic sequence; and the arithmetic sequence calculation part is used for receiving the values Umin, Umax and n, and calculating voltage values U1, U2 . . . Un constituting the arithmetic sequence; wherein the arithmetic sequence calculation unit sequentially inputs the voltage values in the arithmetic sequence to the anode negative high voltage control unit 10.

According to the specifications of the experimental magnetron itself, input the minimum value of the anode working voltage Umin in the input part of the minimum value of the anode operating voltage, input the maximum value of the anode operating voltage Umax in the input part of the maximum value of the anode operating voltage, and input the equal difference in the part of the voltage value quantity. The number of voltage values of the sequence is n, and the arithmetic sequence calculation part calculates the voltage values U1, U2 . . . The voltage value is input to the anode negative high voltage control unit 10, and the anode negative high voltage control unit 10 controls the anode negative high voltage power supply 5 to supply the voltage value of the arithmetic sequence as the anode voltage.

The control device further comprises a target power input part and a power calculation part; the target power input part is used for inputting the experimental magnetron target output power P0 to the power calculation part; the power calculation part is used for calculating the experimental magnetron output power P according to the anode current the anode current value Ia read in real time by the anode current measuring part 7 and the anode voltage value Ui read by the anode negative high voltage measuring unit 8, and determining whether P is equal to P0.

The target power input unit inputs the experimental magnetron target output power P0 to the power calculation unit, and the power calculation unit uses the anode current value Ia read in real time by the anode current measuring unit 7 and the anode voltage value Ui read by the anode negative high voltage measuring unit 8 The experimental magnetron output power P is calculated, and if P is equal to P0, the temperature measuring unit 12 measures the temperature of the cathode filament 1 as Ti.

The control device further comprises a magnet coil working current minimum value input part and a magnet coil working current maximum value input part; the magnet coil working current minimum value input part is used for inputting the magnet coil working current minimum value Imin; the magnet coil working current maximum value input part is used for inputting the maximum value Imax of the working current of the magnet coil; the coil current control part 11 receives Imin and Imax, and controls the magnetic field power supply 6 to adjust the magnet coil current among Imin-Imax.

Input the minimum value of the working current of the magnet coil Imin to the input part of the minimum value of the working current of the magnet coil, and input the maximum value of the working current of the magnet coil Imax to the input part of the maximum value of the working current of the magnet coil, so that the coil current control part 11 can control the magnetic field power supply 6 to be between Imin˜Adjust the magnet coil current between Imax to find the anode voltage value Ui and the magnet coil current value Ic where P is equal to P0.

The control device further comprises a temperature data set storage part; when the power calculation part judges that P is equal to P0, the temperature data set storage part stores a temperature Ti of the cathode filament 1 measured by the temperature measurement part 12, and stores a corresponding temperature of each Ti and the anode voltage value Ui and the magnet coil current value Ic; and the temperature data set storage unit stores all temperatures Ti of the cathode filament 1 to form a temperature data set.

The control device further comprises a parameter screening part; wherein the parameter screening part is configured to screen out the minimum temperature value Tmin in the temperature data set, read the anode voltage value and the magnet coil current value corresponding to Tmin, and output the anode voltage value and the current value of the magnet coil to the working magnetron. Under the parameters of the anode voltage value and the magnet coil current value corresponding to Tmin, the working magnetron realizes the lower temperature of the cathode filament 1 when the output power is P0, thereby prolonging the life of the magnetron.

The present invention will be described in further detail below with reference to the accompanying drawings and specific embodiments, but the present invention is not limited to the following embodiments.

What is claimed is:

1. A method for improving service life of a magnetron, comprising: adopting a control device, an experimental magnetron and a working magnetron; wherein the experimental magnetron comprises a cathode filament (1), a an anode (2) matching with the cathode filament (1), an electromagnet (3), a cathode power supply (4), an anode negative high-voltage power supply (5) and a magnetic field power supply (6); wherein the cathode power supply (4) is used for heating the cathode filament (1); the anode negative high-voltage power supply (5) is used for providing the anode voltage, so that the anode (2) and the cathode filament (1) are arranged to generate an electric field; the magnetic field power supply (6) is used for providing the coil of the electromagnet (3) with a magnet coil current, in such a manner that the electromagnet (3) generates a magnetic field of an orthogonal electric field; the control device comprises an anode current measuring part (7) for measuring anode current, an anode negative high voltage measuring part (8) for measuring anode voltage; a coil current measuring unit (9) for measuring magnet coil current, an anode negative high voltage control unit (10) for changing anode voltage, a coil current control unit (11) for changing magnet coil current, and a temperature measuring unit (12) for measuring a temperature of the cathode filament (1); wherein the method specifically comprise steps of:
step (1): setting experimental magnetron target output power to be P0, working voltage range of the anode (2) in a range of Umin-Umax, and magnet coil working current to be in a range of Imin-Imax;
step (2): taking n voltage values U1, U2 . . . Un forming an arithmetic progression from the working voltage range Umin˜Umax of the anode (2), wherein U1=Umin, Un=Umax;
step (3): taking a first voltage value in the arithmetic sequence as the anode voltage Ui;
step (4): by the anode negative high voltage control part (10), controlling the anode negative high voltage power supply (5) to provide the anode voltage for Ui, and reading the anode voltage value by the anode negative high voltage measuring part (8);
step (5): when the anode negative high voltage measuring unit (8) reads the anode voltage as Ui, controlling the magnetic field power supply (6) by the coil current control unit (11) to adjust the magnet coil current between Imin and Imax; reading the magnet coil current value Ic in real time by the coil current measuring unit (9); reading the anode current value Ia in real time by the anode current measuring section (7);
according to the anode current value Ia and the anode voltage value Ui, when the experimental magnetron output power P is calculated to be equal to P0, performing step (6); if the output power P of the experimental magnetron is not equal to P0, then performing step (7);
step (6): by the temperature measuring part (12), measuring the temperature of the cathode filament (1) as Ti; and recording the anode voltage value Ui and the magnet coil current value Ic when the experimental magnetron output power P is equal to P0;
step (7): if Ui is not a last value of the arithmetic sequence, performing step (8); otherwise performing step (9);
step (8): taking a voltage value of a next digit of Ui in the arithmetic sequence as Ui, and performing step (4);
step (9): adopting the temperature measuring unit (12) to measure the temperature Ti of all the cathode filaments (1), and taking Ti as the temperature data set corresponding to P0; taking out a minimum temperature value Tmin in the temperature data set, an anode voltage value and a current value of the magnet coil corresponding to Tmin;
step (10): taking the anode voltage value and the current value of the magnet coil corresponding to Tmin obtained in step (9) as the anode voltage value and the magnet coil current value with the output power of the working magnetron being P0.

2. The method for improving the service life of the magnetron, as recited in claim 1, wherein the control device further comprises an anode working voltage minimum value input part, an anode working voltage maximum value input part, a voltage value quantity part and an arithmetic sequence calculation part; wherein the anode working voltage minimum value input part is used for inputting a anode working voltage minimum value Umin; the anode working voltage maximum value input part is used for inputting a anode working voltage maximum value Umax; the voltage value quantity part is used for inputting an amount of a voltage values n of the arithmetic sequence; and the arithmetic sequence calculation part is used for receiving the values Umin, Umax and n, and calculating voltage values U1, U2 . . . Un constituting the arithmetic sequence; wherein the arithmetic sequence calculation unit sequentially inputs the voltage values in the arithmetic sequence to the anode negative high voltage control unit (10).

3. The method for improving the service life of the magnetron, as recited in claim 2, wherein the control device further comprises a target power input part and a power calculation part; the target power input part is used for inputting the experimental magnetron target output power P0 to the power calculation part; the power calculation part is used for calculating the experimental magnetron output power P according to the anode current the anode current value Ia read in real time by the anode current measuring part (7) and the anode voltage value Ui read by the anode negative high voltage measuring unit (8), and determining whether P is equal to P0.

4. The method for improving the service life of the magnetron, as recited in claim 3, wherein the control device further comprises a magnet coil working current minimum value input part and a magnet coil working current maximum value input part; the magnet coil working current minimum value input part is used for inputting the magnet coil working current minimum value Imin; the magnet coil working current maximum value input part is used for inputting the maximum value Imax of the working current of the magnet coil; the coil current control part (11) receives Imin and Imax, and controls the magnetic field power supply (6) to adjust the magnet coil current among Imin-Imax.

5. The method for improving the service life of the magnetron, as recited in claim 4, wherein the control device further comprises a temperature data set storage part; when the power calculation part judges that P is equal to P0, the temperature data set storage part stores a temperature Ti of the cathode filament (1) measured by the temperature measurement part (12), and stores a corresponding temperature of each Ti and the anode voltage value Ui and the magnet coil current value Ic; and the temperature data set storage unit stores all temperatures Ti of the cathode filament (1) to form a temperature data set.

6. The method for improving the service life of the magnetron, as recited in claim 5, wherein the control device further comprises a parameter screening part; wherein the parameter screening part is configured to screen out the minimum temperature value Tmin in the temperature data set, read the anode voltage value and the magnet coil current value corresponding to Tmin, and output the anode voltage value and the current value of the magnet coil to the working magnetron.
